(19) United States
(12) Patent Application Publication
(10) Pub. No.: US 2026/0329036 A1
(43) Pub. Date: Oct. 22, 2026

(54) ELECTRONIC DEVICE BASED ON WAFER-ON-WAFER PACKAGING TECHNOLOGY

(71) Applicant: WHALECHIP CO., LTD., Taipei (TW)

(72) Inventor: Kun-Hua TSAI, Taipei (TW)

(73) Assignee: WHALECHIP CO., LTD., Taipei (TW)

(21) Appl. No.: 19/565,456

(22) Filed: Mar. 12, 2026

(30) Foreign Application Priority Data
Mar. 14, 2025 (CN) 2025103028346

(51) Int. Cl. G02B 6/43; H10F 39/90

(52) U.S. Cl. CPC G02B 6/43; H10F 39/90

(57) ABSTRACT

An electronic device based on wafer on WoW packaging technology includes a first circuit layer, a second circuit layer and a waveguide connector. Each of the first circuit layer and the second circuit layer includes a photoelectric conversion device for emitting or receiving an optical signal. The waveguide connector is disposed between the first circuit layer and the second circuit layer for transmitting the optical signal. The electronic device may achieve high-speed data transmission by transmitting optical signals in different circuit layers.

### CROSS-REFERENCE TO RELATED APPLICATION

This application claims the priority benefit of Chinese Patent Application Serial Number 2025103028346, filed on Mar. 14, 2025, the full disclosure of which is incorporated herein by reference.

### BACKGROUND OF THE INVENTION

### Technical Field

The present disclosure relates to an electronic device and, more particularly, to an electronic device based on wafer-on-wafer packaging technology.

### Prior Art

In recent years, in order to improve the performance of a chip device without increasing the volume or the footprint of the chip device, it is proposed to adopt three-dimensional packaging technology (e.g., wafer-on-wafer (WoW) technology) can integrate dice provided with various properties by various processes.

The characteristic of the aforementioned three-dimensional packaging technology is that the dice may be stacked on one another and perform digital signal transmission through the direct connections between contact points. In other words, the transmission bandwidth of the dice is directly related to the number of the contact points.

However, under a circumstance that data transmission requirements increase yearly, the number of the contact points needs increasing accordingly, thereby raising the overall cost of the dice. In addition, the contact points have an upper limit on transmission speed because of the constraints of the physical properties thereof and can not satisfy the continuous growth of the data transmission requirements. Furthermore, in order to transmit plenty of data, the dice are prone to be at high temperature, which results in raising the overall power consumption of the dice and diminishing the overall operational efficiency of the dice.

Accordingly, how to provide an electronic device which is suitable for the wafer-on-wafer (WoW) packaging technology and realizes high-speed data transmission is one of the problems to be resolved in the art

### SUMMARY OF THE INVENTION

The embodiments of the present disclosure provide an electronic device based on the wafer-on-wafer packaging technology which performs high-speed data transmission by optical signals. Thus, the number of the contact points of the electronic device which the data transmission requires may be reduced, and the manufacturing costs and the operating power consumption of electronic devices are thus reduced.

One aspect of the present disclosure is to provide an electronic device based on the wafer-on-wafer packaging technology. The electronic device includes a first circuit layer, a second circuit layer and a waveguide connector. The first circuit layer includes a first circuit block and a first photoelectric conversion device. The first photoelectric conversion device is configured to emit or receive an optical signal. The second circuit layer includes a second circuit block and a second photoelectric conversion device. The second circuit layer is stacked on the first circuit layer. The second photoelectric conversion device is configured to emit or receive the optical signal. The waveguide connector is disposed between the first circuit layer and the second circuit layer. The waveguide connector is configured to transmit the optical signal along a first direction which is parallel to the stacking direction of the first circuit layer and the second circuit layer.

According to the above description, the electronic device includes the first photoelectric conversion device, the second photoelectric conversion device, and the waveguide connector. The first photoelectric conversion device and the second photoelectric conversion device located on the different circuit layers may transmit or receive the optical signal through the waveguide connector. The different circuit layers of the electronic device may implement the high-speed data transmission by the optical signal. Accordingly, the number of the contact points of the electronic device which the data transmission requires may be reduced to implement the high-speed data transmission, thereby reducing the manufacturing costs and the operating power consumption of the electronic device.

### BRIEF DESCRIPTION OF DRAWINGS

The accompanying drawings herein are provided to have advanced understanding on the present application and constitute one part of the present disclosure. The exemplary embodiments and the explanations of the present application are used to explain the present disclosure instead of constituting the inappropriate restrictions of the present disclosure. In the drawings:

FIG. 1 is a schematic diagram of an embodiment of a wafer product according to an embodiment of the present disclosure;

FIG. 2 is a schematic diagram of an embodiment of an electronic device according to an embodiment of the present disclosure;

FIG. 3 is a schematic diagram of a system architecture of a photoelectric conversion device according to an embodiment of the present disclosure;

FIG. 4 is a schematic diagram of a first configuration embodiment of a photoelectric conversion device according to an embodiment of the present disclosure;

FIG. 5 is a schematic diagram of a second configuration embodiment of a photoelectric conversion device according to an embodiment of the present disclosure;

FIG. 6 is a schematic diagram of a third configuration embodiment of a photoelectric conversion device according to an embodiment of the present disclosure;

FIG. 7 is a schematic diagram of a fourth configuration embodiment of a photoelectric conversion device according to an embodiment of the present disclosure;

FIG. 8 is a schematic diagram of a fifth configuration embodiment of a photoelectric conversion device according to an embodiment of the present disclosure; and

FIG. 9 is a schematic diagram of a sixth configuration embodiment of a photoelectric conversion device according to an embodiment of the present disclosure.

### DETAILED DESCRIPTION OF THE INVENTION

The technical solutions in the embodiments of the present disclosure will be described clearly and completely below in conjunction with the accompanying drawings in the embodiments of the present disclosure. Apparently, the described embodiments are merely one part of the embodiments of the present disclosure and not all embodiments of the present disclosure. Based on the embodiments of the present disclosure, all embodiments obtained by a person skilled in the art without any inventive steps shall fall within the scope of protection of the present disclosure.

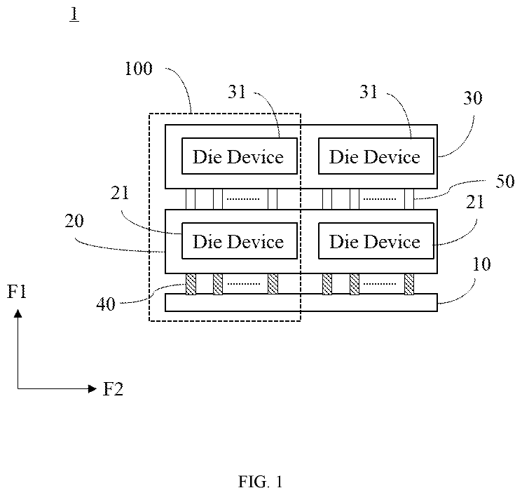

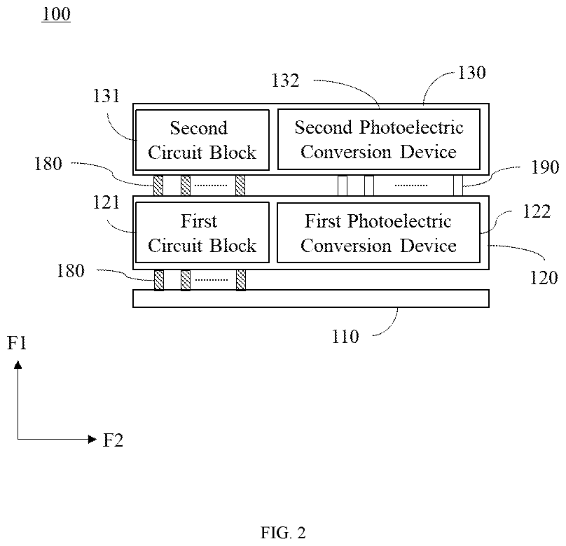

Please refer to FIG. 1 and FIG. 2. FIG. 1 is a schematic diagram of an embodiment of a wafer product according to an embodiment of the present disclosure. FIG. 2 is a schematic diagram of an embodiment of an electronic device according to an embodiment of the present disclosure. The wafer product 1 includes a base 10, a first circuit layer 20 and a second circuit layer 30. Each of the first circuit layer 20 and the second circuit layer 30 may be implemented by a wafer. The first circuit layer 20 is disposed on the base 10 along a first direction F1 and is connected to the base 10 via at least one electrical connector 40. The first circuit layer 20 establishes a communication connection with the base 10 via the at least one electrical connector 40. The first circuit layer 20 includes a plurality of die devices 21. The second circuit layer 30 is disposed on the first circuit layer 20 along the first direction F1 and is connected to the first circuit layer 20 via at least one waveguide connector 50. The second circuit layer 30 establishes a communication connection with the first circuit layer 20 via the at least one waveguide connector 50. The second circuit layer 30 includes a plurality of die devices 31. The wafer product 1 is a semi-finished product of an electronic device 100. The wafer product 1 after wafer dicing yields a plurality of electronic devices 100. In the present embodiment, the arrangements of the first circuit layer 20 and the second circuit layer 30 are provided merely by way of example. One or more wafers may be disposed between the first circuit layer 20, the second circuit layer 30, and the base 10 according to requirements.

The electronic device 100 includes a base 110, a first circuit layer 120 and a second circuit layer 130. The base 110 is diced from the base 10. The substrate base 110 is, for example, a substrate, a silicon interposer, or the combination of the substrate and the silicon interposer. The first circuit layer 120 is disposed on the base 110 along the first direction F1. The first circuit layer 120 is diced from the first circuit layer 20. The first circuit layer 120 is connected to the base 110 through the at least one electrical connector 180. In the embodiment, the number of the at least one electrical connector 180 is multiple. The first circuit layer 120 establishes the communication connection with the base 110 via the electrical connectors 180. Each of the electrical connector 180 is, for example, a contact pillar implemented by hybrid bonding technology. For example, the first circuit layer 120 and the second circuit layer 130 are connected to each other by the contact pillars implemented by hybrid bonding technology. In one embodiment, the at least one electrical connector 180 is, for example, a C2 (Chip Connection) bump or a C4 (Controlled Collapse of Chip Connection) bump. For example, the first circuit layer 120 may be connected to the base 110 via the C2 bump or the C4 bump.

The first circuit layer 120 includes a first circuit block 121 and a first photoelectric conversion device 122. That is, the die device 21 may include the first circuit block 121 and the first photoelectric conversion device 122. The first circuit block 121 and the first photoelectric conversion device 122 may be electrically connected to each other through at least one wiring layer (not shown) in the first circuit layer 120. The first circuit block 121 may be, for example, a logic circuit or a storage device, and be not limited thereto. The first photoelectric conversion device 122 is configured to convert an electrical signal corresponding to data from the first circuit block 121 into an optical signal and to emit the optical signal. The first photoelectric conversion device 122 is configured to receive the optical signal from another photoelectric conversion device, and converts the received optical signal into the electrical signal to provide the electrical signal for the first circuit block 121. Thus, the first photoelectric conversion device 122 realizes the data transmission between the first circuit block 121 and the other circuit blocks via the optical signals.

The second circuit layer 130 is disposed on the first circuit layer 120 along the first direction F1. The second circuit layer 130 is diced from the second circuit layer 30. The second circuit layer 130 is connected to the first circuit layer 120 via the electrical connectors 180 and the at least one waveguide connector 190. The second circuit layer 130 establishes the communication connection with the first circuit layer 120 via the at least one electrical connector 180 and the at least one waveguide connector 190. The at least one waveguide connector 190 is configured to transmit the optical signal. The at least one waveguide connector 190 is, for example, a connector made of glass, polymers, or semiconductors. In the embodiment, the number of the at least one waveguide connector 190 is multiple.

The second circuit layer 130 includes a second circuit block 131 and a second photoelectric conversion device 132. That is, the die device 31 may include the second circuit block 131 and the second photoelectric conversion device 132. The second circuit block 131 and the second photoelectric conversion device 132 may be electrically connected to each other via the at least one wiring layer (not shown) in the second circuit layer 130. The second circuit block 131 may be, for example, the logic circuit or the storage device, and be not limited thereto. The second circuit block 131 may establish a communication connection with the first circuit block 121 via the electrical connectors 180. The second photoelectric conversion device 132 establishes a communication connection with the first photoelectric conversion device 122 via the waveguide connectors 190. The second photoelectric conversion device 132 is configured to convert an electrical signal corresponding to data from the second circuit block 131 into an optical signal and to emit the optical signal. The second photoelectric conversion device 132 is configured to receive the optical signal from the first photoelectric conversion device 122, and converts the received optical signal into an electrical signal to provide the electrical signal for the second circuit block 131. The second photoelectric conversion device 132 realizes the data transmission between the second circuit block 131 and the other circuit blocks via the optical signal. Because the transmission speed of the optical signal may reach gigahertz (GHz) levels, the first circuit block 121 and the second circuit block 131 may implement the high-speed data transmission via the optical signals under the requirements of transmitting plenty of data. In this way, the number of the electrical connectors of the electronic device 100 which the data transmission requires may be reduced, the manufacturing costs of the electronic device 100 may be diminished, and the electrical connectors are effectively prevented from being in a high-temperature environment on account of the high-speed data transmission, thereby reducing the manufacturing costs and the operating power consumption of the electronic device 100.

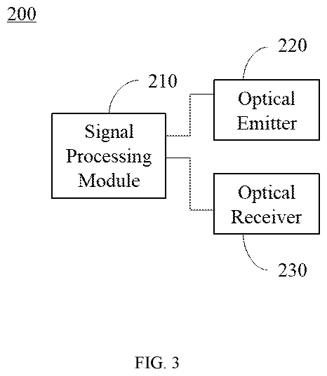

Please refer to FIG. 3. FIG. 3 is a schematic diagram of a system architecture of a photoelectric conversion device according to an embodiment of the present disclosure. The first photoelectric conversion device 122 and the second photoelectric conversion device 132 may be implemented by the embodiment of FIG. 3. The photoelectric conversion device 200 includes a signal processing module 210, an optical emitter 220, and an optical receiver 230. The signal processing module 210 is electrically connected to the optical emitter 220 and the optical receiver 230. The photoelectric conversion device 200 may be implemented by co-packaged optics (CPO) technology. The signal processing module 210 is electrically connected to an external circuit (e.g., first circuit block 121 or second circuit block 131). The signal processing module 210 is configured to generate control signals for the optical emitter 220 based on the received data. The signal processing module 210 is configured to receive the electrical signals from the optical receiver 230 and to transmit the electrical signals to the external circuit electrically connected to the signal processing module 210. The signal processing module 210 may be implemented by an electronic integrated circuit (EIC). The optical emitter 220 emits light according to the control signal from the signal processing module 210 to generate the optical signals corresponding to the data to be transmitted. The optical emitter 220 is, for example, a micro-light-emitting diode array or a laser diode array. In one embodiment, the optical emitter 220 is implemented by the micro-light-emitting diode array. In one embodiment, the optical emitter 220 is configured to emit blue light to effectively reduce power required for optical signal transmission. The optical receiver 230 is configured to sense the optical signals, and converts the sensed optical signals into the electrical signals and transmits them to the signal processing module 210. The optical receiver 230 is, for example, a photodiode array. The optical emitter 220 and the optical receiver 230 may be implemented by a photonics integrated circuit (PIC). The photoelectric conversion device 200 implemented by the co-packaged optics technology may significantly reduce the overall size of the photoelectric conversion device 200 and is combined with advanced processes (e.g., the wafer-on-wafer packaging technology) to simplify the process of the electronic device 100 to enhance the convenience of the electronic device 100 in manufacturing.

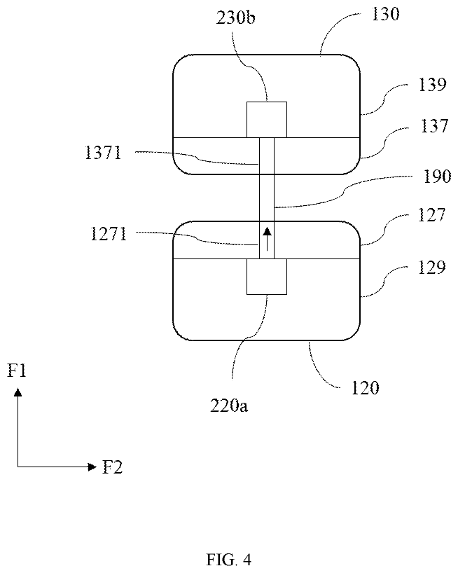

Please refer to FIG. 2 and FIG. 4. FIG. 4 is a schematic diagram of a first configuration embodiment of a photoelectric conversion device according to an embodiment of the present disclosure. In the present embodiment, the configuration of the photoelectric conversion device would be elaborated by taking the optical emitter 220a and the optical receiver 230b as an example. The optical emitter 220a may be the optical emitter 220 of the first photoelectric conversion device 122, and the optical receiver 230b may be the optical receiver 230 of the second photoelectric conversion device 132. In the present embodiment, the first circuit layer 120 includes a first sub-layer 127 and a second sub-layer 129 which are stacked with each other. The optical emitter 220a is disposed in the second sub-layer 129. The first circuit layer 120 further includes a first optical waveguide element 1271. The first optical waveguide element 1271 is disposed in the first sub-layer 127. The first optical waveguide element 1271 is, for example, the connector made of the glass, the polymers, or the semiconductors. The first optical waveguide element 1271 is connected to the waveguide connector 190 and the optical emitter 220a in the first direction F1. Therefore, the first optical waveguide element 1271 and the optical emitter 220a are located in the different sub-layers of the first circuit layer 120. The first optical waveguide element 1271 is configured to transmit the optical signal emitted by the optical emitter 220a.

The second circuit layer 130 includes a first sub-layer 137 and a second sub-layer 139 which are stacked with each other. The optical receiver 230b is disposed in the second sub-layer 139. The second circuit layer 130 further includes a second optical waveguide element 1371. The second optical waveguide element 1371 is disposed in the first sub-layer 137. The second optical waveguide element 1371 is, for example, the connector made of the glass, the polymers, or the semiconductors. The second optical waveguide element 1371 is connected to the waveguide connector 190 and the optical receiver 230b in the first direction F1. Therefore, the second optical waveguide element 1371 and the optical receiver 230b are located in the different sub-layers of the second circuit layer 130. The second optical waveguide element 1371 is configured to transmit the optical signal from the optical emitter 220a. Therefore, in the present embodiment, the first optical waveguide element 1271, the waveguide connectors 190, and the second optical waveguide element 1371 form an optical channel that transmits the optical signal along the first direction F1. The optical emitter 220a emits the optical signal toward the first optical waveguide element 1271 along the first direction F1, and the optical receiver 230b senses the optical signal along the first direction F1. In the present embodiment, the vertical projection of the waveguide connector 190 onto the first circuit layer 120 or the second circuit layer 130 overlaps with each of the vertical projections of the optical emitter 220a and the optical receiver 230b onto the first circuit layer 120 or the second circuit layer 130. In the present embodiment, the first circuit block 121 and the optical emitter 220a are located in the same sub-layer of the first circuit layer 120, and the second circuit block 131 and the optical receiver 230b are located in the same sub-layer of the second circuit layer 130. In one embodiment, the optical receiver 230 of the first photoelectric conversion device 122 may be implemented by the optical receiver 230b, and the optical emitter 220 of the second photoelectric conversion device 132 may be implemented by the optical emitter 220a. Accordingly, the arrangement and the connection relationship of the optical receiver 230 of the first photoelectric conversion device 122 and the optical emitter 220 of the second photoelectric conversion device 132 are not repeated in detail herein.

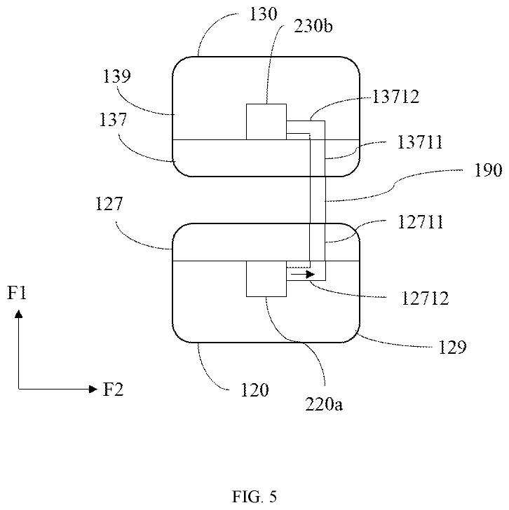

Please refer to FIG. 5. FIG. 5 is a schematic diagram of a second configuration embodiment of a photoelectric conversion device according to an embodiment of the present disclosure. The difference between the embodiment in FIG. 5 and FIG. 4 is that the first optical waveguide element 1271, the waveguide connector 190, and the second optical waveguide element 1371 form a U-shaped optical channel. In the present embodiment, the first optical waveguide element 1271 includes a bending portion 12712 and a connecting portion 12711. The bending portion 12712 is disposed in the second sub-layer 129, and the connecting portion 12711 is disposed in the first sub-layer 127. One end of the bending portion 12712 is connected to the optical emitter 220a in a second direction F2. The second direction F2 is perpendicular to the first direction F1. The other end of the bending portion 12712 is connected to the connecting portion 12711 in the first direction F1. The connecting portion 12711 is connected to the waveguide connector 190 in the first direction F1. Therefore, a part of the first optical waveguide element 1271 (i.e., the bending portion 12712) and the optical emitter 220a are located in the same sub-layer of the first circuit layer 120.

The second optical waveguide element 1371 includes a bending portion 13712 and a connecting portion 13711. The bending portion 13712 is disposed in the second sub-layer 139, and the connecting portion 13711 is disposed in the first sub-layer 137. One end of the bending portion 13712 is connected to the optical receiver 230b in the second direction F2. The other end of the bending portion 13712 is connected to the connecting portion 13711 in the first direction F1. The connecting portion 13711 is connected to the waveguide connector 190 on the first direction F1. Thus, a part of the second optical waveguide element 1371 (i.e., the bending portion 13712) and the optical receiver 230b are located in the same sub-layer of the first circuit layer 120. Therefore, in the present embodiment, the first optical waveguide element 1271, the waveguide connector 190, and the second optical waveguide element 1371 form the U-shaped optical channel. The optical emitter 220a emits the optical signal toward the first optical waveguide element 1271 along the second direction F2, and the optical receiver 230b senses the optical signal in the second direction F2. In the present embodiment, the vertical projection of the waveguide connector 190 onto the first circuit layer 120 or the second circuit layer 130 does not overlap with each of the vertical projections of the optical emitter 220a and the optical receiver 230b onto the first circuit layer 120 or the second circuit layer 130. In the present embodiment, the first circuit block 121 and the optical emitter 220a are located in the same sub-layer of the first circuit layer 120, and the second circuit block 131 and the optical receiver 230b are located in the same sub-layer of the second circuit layer 130. In one embodiment, the optical receiver 230 of the first photoelectric conversion device 122 may be implemented by the optical receiver 230b, and the optical emitter 220 of the second photoelectric conversion device 132 may be implemented by the optical emitter 220a. Accordingly, the arrangement and the connection relationship of the optical receiver 230 of the first photoelectric conversion device 122 and the optical emitter 220 of the second photoelectric conversion device 132 are not repeated in detail herein.

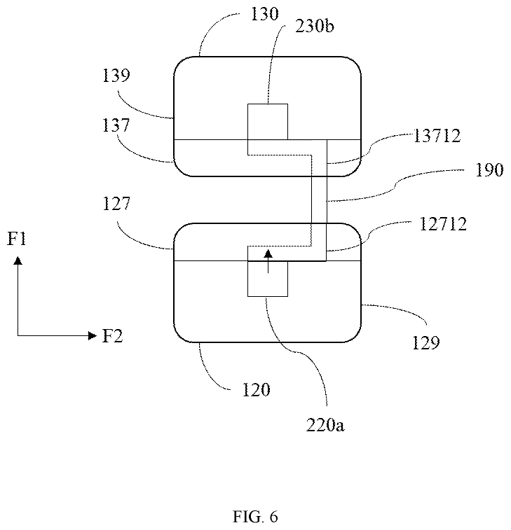

Please refer to FIG. 6. FIG. 6 is a schematic diagram of a third configuration embodiment of a photoelectric conversion device according to an embodiment of the present disclosure. The difference between the embodiment in FIG. 6 and FIG. 5 is that the first optical waveguide element 1271 is implemented as the bending portion 12712, and the second optical waveguide element 1371 is implemented as the bending portion 13712. In the embodiment, the bending portion 12712 is disposed in the first sub-layer 127. One end of the bending portion 12712 is connected to the optical emitter 220a in the first direction F1. The other end of the bending portion 12712 is connected to the waveguide connector 190 in the first direction F1. Therefore, a part of the first optical waveguide element 1271 (i.e., the bending portion 12712) and the optical emitter 220a are located in the different sub-layers of the first circuit layer 120. One end of the bending portion 13712 is connected to the optical receiver 230b in the first direction F1. The other end of the bending portion 13712 is connected to the waveguide connector 190 in the first direction F1. Thus, a part of the second optical waveguide element 1371 (i.e., the bending portion 13712) and the optical receiver 230b are located in the different sub-layers of the first circuit layer 120. Therefore, in the present embodiment, the first optical waveguide element 1271, the waveguide connector 190, and the second optical waveguide element 1371 form the U-shaped optical channel. The optical emitter 220a emits the optical signal along the first direction F1 toward the first optical waveguide element 1271, and the optical receiver 230b senses the optical signal along the first direction F1. In the embodiment, the vertical projection of the waveguide connector 190 onto the first circuit layer 120 or the second circuit layer 130 does not overlap with each of vertical projections of the optical emitter 220a and the optical receiver 230b onto the first circuit layer 120 or the second circuit layer 130. In the present embodiment, the first circuit block 121 and the optical emitter 220a are located in the same sub-layer of the first circuit layer 120, and the second circuit block 131 and the optical receiver 230b are located in the same sub-layer of the second circuit layer 130. In one embodiment, the optical receiver 230 of the first photoelectric conversion device 122 may be implemented by optical receiver 230b, and the optical emitter 220 of the second photoelectric conversion device 132 may be implemented by optical emitter 220a. Accordingly, the arrangement and connection relationship of the optical receiver 230 of the first photoelectric conversion device 122 and the optical emitter 220 of the second photoelectric conversion device 132 are not repeated in detail herein.

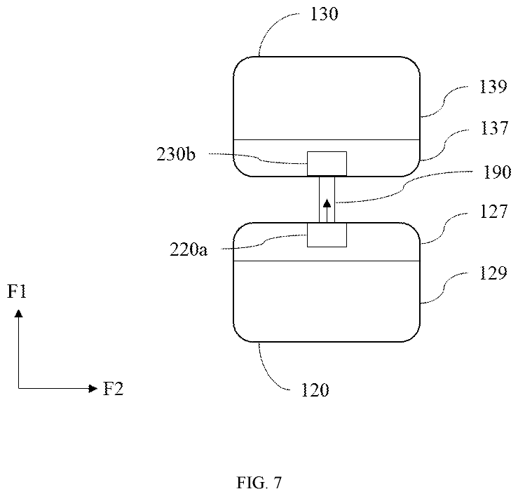

Please refer to FIG. 7. FIG. 7 is a schematic diagram of a fourth configuration embodiment of a photoelectric conversion device according to an embodiment of the present disclosure. The difference between FIG. 7 and FIG. 4 is that the optical emitter 220a is disposed in the first sub-layer 127 of the first circuit layer 120, and the optical receiver 230b is disposed in the first sub-layer 137 of the second circuit layer 130. In the embodiment, the materials of the first sub-layer 127 and the second sub-layer 129 of the first circuit layer 120 are different, and the materials of the first sub-layer 137 and the second sub-layer 139 of the second circuit layer 130 are different. For example, the materials of the first sub-layer 127 and the first sub-layer 137 are III-V compounds, and the materials of the second sub-layer 129 and the second sub-layer 139 are silicon. The optical emitter 220a is disposed in the first sub-layer 127 and is connected to the waveguide connector 190. The optical receiver 230b is disposed in the first sub-layer 137 and is connected to the waveguide connector 190. Thus, in the present embodiment, the optical emitter 220a emits the optical signal toward the waveguide connector 190 along the first direction F1, and the optical receiver 230b senses the optical signal along the first direction F1. In the present embodiment, the vertical projection of the waveguide connector 190 onto the first circuit layer 120 or the second circuit layer 130 overlaps with each of the vertical projections of the optical emitter 220a and the optical receiver 230b onto the first circuit layer 120 or the second circuit layer 130. In the present embodiment, the first circuit block 121 and the optical emitter 220a are located in the different sub-layers of the first circuit layer 120, and the second circuit block 131 and the optical receiver 230b are located in the different sub-layers of the second circuit layer 130. In one embodiment, the optical receiver 230 of the first photoelectric conversion device 122 may be implemented by the optical receiver 230b, and the optical emitter 220 of the second photoelectric conversion device 132 may be implemented by the optical emitter 220a. Therefore, the configuration and connection relationship of the optical receiver 230 of the first photoelectric conversion device 122 and the optical emitter 220 of the second photoelectric conversion device 132 are not repeated in detail herein.

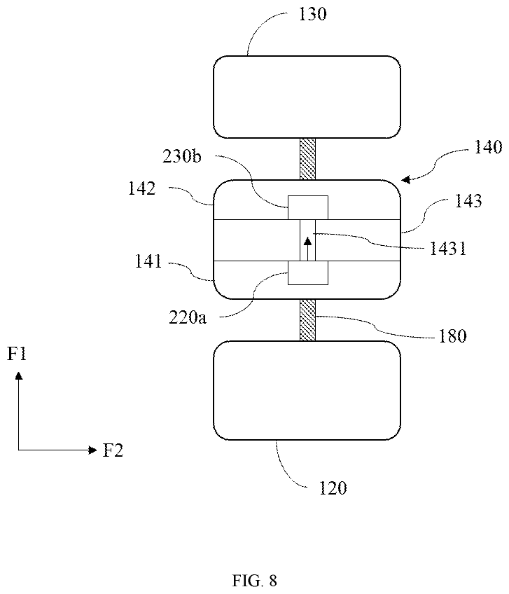

Please refer to FIG. 8. FIG. 8 is a schematic diagram of a fifth configuration embodiment of a photoelectric conversion device according to an embodiment of the present disclosure. In the embodiment, the electronic device 100 includes a photoelectric transport layer 140. The material of the photoelectric transport layer 140 is, for example, the III-V compounds. The photoelectric transport layer 140 is located between the first circuit layer 120 and the second circuit layer 130, and is connected to the first circuit layer 120 and the second circuit layer 130 via the plurality of electrical connectors 180. The photoelectric transport layer 140 includes a first sub-layer 141, a second sub-layer 142, and a third sub-layer 143. The first sub-layer 141 is communicatively connected to the first circuit layer 120 through the electrical connector 180. The second sub-layer 142 is communicatively connected to the second circuit layer 130 through the electrical connector 180. The third sub-layer 143 is located between the first sub-layer 141 and the second sub-layer 142. The optical emitter 220a of the first photoelectric conversion device 122 is disposed in the first sub-layer 141. The optical receiver 230b of the second photoelectric conversion device 132 is disposed in the second sub-layer 142. There is at least one internal optical waveguide connector 1431 in the third sub-layer 143. The internal optical waveguide connector 1431 is, for example, the connector made of the glass, the polymers, or the semiconductors. The optical emitter 220a and the optical receiver 230b transmit the optical signal via the at least one internal optical waveguide connector 1431. For example, the optical emitter 220a and the optical receiver 230b are connected to each other via the at least one internal optical waveguide connector 1431 to transmit the optical signal. Thus, in the present embodiment, the optical emitter 220a emits the optical signal along the first direction F1 toward the connected internal optical waveguide connector 1431, and the optical receiver 230b senses the optical signal along the first direction F1. In the present embodiment, the vertical projection of the at least one internal optical waveguide connector 1431 onto the first circuit layer 120 or the second circuit layer 130 overlaps with each of the vertical projections of the optical emitter 220a and the optical receiver 230b onto the first circuit layer 120 or the second circuit layer 130. In the present embodiment, the first circuit block 121 and the optical emitter 220a are located on different layers, and the second circuit block 131 and the optical receiver 230b are located on different layers. In one embodiment, the optical receiver 230 of the first photoelectric conversion device 122 is disposed in the first sub-layer 141, and the optical emitter 220 of the second photoelectric conversion device 132 may be disposed in the second sub-layer 142. The optical receiver 230 of the first photoelectric conversion device 122 is connected to the optical emitter 220 of the second photoelectric conversion device 132 via the at least some internal optical waveguide connectors 1431 to transmit the optical signals.

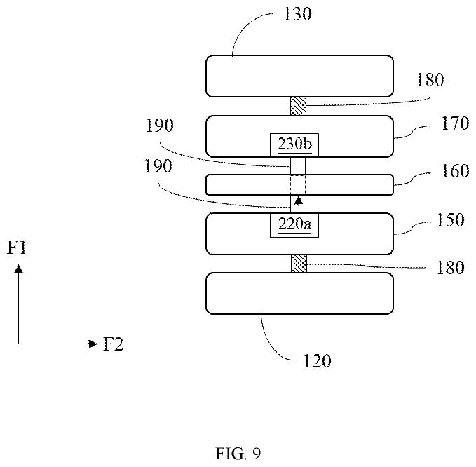

Please refer to FIG. 9. FIG. 9 is a schematic diagram of a sixth configuration embodiment of a photoelectric conversion device according to an embodiment of the present disclosure. The electronic device 100 further includes a first photoelectric transport layer 150, a waveguide connecting layer 160, and a second photoelectric transport layer 170. The materials of the first photoelectric transport layer 150 and the second photoelectric transport layer 170 are, for example, the III-V compounds. The material of the waveguide connecting layer 160 is, for example, the glass, the polymer or the semiconductors. The first photoelectric transport layer 150 is stacked on the first circuit layer 120 and is connected to the first circuit layer 120 via the electrical connector 180. The optical emitter 220a of the first photoelectric conversion device 122 is disposed in the first photoelectric transport layer 150. The waveguide connecting layer 160 is stacked on the first photoelectric transport layer 150. The waveguide connecting layer 160 is connected to the first photoelectric transport layer 150 via the waveguide connector 190 and is configured to receive or transmit the optical signal. The second photoelectric transport layer 170 is stacked on the waveguide connecting layer 160, and is connected to the waveguide connecting layer 160 via the waveguide connector 190, and is connected to the second circuit layer 130 via the electrical connector 180. The optical receiver 230b of the second photoelectric conversion device 132 is disposed in the second photoelectric transport layer 170. The optical emitter 220a and the optical receiver 230b transmit the optical signals via the waveguide connector 190 and the waveguide connecting layer 160. For example, the optical signal emitted by the optical emitter 220a may be transmitted to the optical receiver 230b by sequentially passing through the waveguide connector 190, the waveguide connecting layer 160, and the waveguide connector 190. Therefore, in the present embodiment, the optical emitter 220a emits the optical signal toward the connected waveguide connector 190 along the first direction F1, and the optical receiver 230b senses the optical signal along the first direction F1. In the present embodiment, the vertical projection of the waveguide connector 190 onto the first circuit layer 120 or the second circuit layer 130 overlaps with each of vertical projections of the optical emitter 220a and the optical receiver 230b onto the first circuit layer 120 or the second circuit layer 130. In the present embodiment, the first circuit block 121 and the optical emitter 220a are located on the different layers, and the second circuit block 131 and the optical receiver 230b are located on the different layers. In one embodiment, the optical receiver 230 of the first photoelectric conversion device 122 may be disposed on the first photoelectric transport layer 150, and the optical emitter 220 of the second photoelectric conversion device 132 may be disposed on the second photoelectric transport layer 170. Therefore, the optical emitter 220 of the second photoelectric conversion device 132 may transmit the optical signal to the optical receiver 230 of the first photoelectric conversion device 122 by sequentially passing through the waveguide connector 190, the waveguide connecting layer 160, and the waveguide connector 190.

According to the above description, the electronic device includes the first photoelectric conversion device, the second photoelectric conversion device, and the waveguide connector. The first photoelectric conversion device and the second photoelectric conversion device located on the different circuit layers may transmit or receive the optical signal through the waveguide connector. The different circuit layers of the electronic device may implement the high-speed data transmission by the optical signal. Accordingly, the number of the contact points of the electronic device which the data transmission requires may be reduced to implement the high-speed data transmission, thereby reducing the manufacturing costs and the operating power consumption of the electronic device.

The terms “include”, “contain”, and any variation thereof are intended to cover a non-exclusive inclusion. Therefore, a process, method, object, or device that comprises a series of elements not only include these elements, but also comprises other elements not specified expressly, or may include inherent elements of the process, method, object, or device. If no more limitations are made, an element limited by “include a/an . . . ” does not exclude other same elements existing in the process, the method, the article, or the device which comprises the element.

What is claimed is:

1. An electronic device base on wafer on wafer packaging technology, comprising:
a first circuit layer, comprising a first circuit block and a first photoelectric conversion device, wherein the first photoelectric conversion device is configured to emit or receive an optical signal;
a second circuit layer, comprising a second circuit block and a second photoelectric conversion device and stacked on the first circuit layer, wherein the second photoelectric conversion device is configured to emit or receive the optical signal; and
a waveguide connector, disposed between the first circuit layer and the second circuit layer and configured to transmit the optical signal along a first direction, wherein the first direction is parallel to a stacking direction of the first circuit layer and the second circuit layer.

2. The electronic device according to claim 1, wherein each of the first photoelectric conversion device and the second photoelectric conversion device is configured to emit or receive the optical signal in the first direction.

3. The electronic device according to claim 1, wherein each of the first photoelectric conversion device and the second photoelectric conversion device is configured to emit or receive the optical signal in a second direction, wherein the second direction is perpendicular to the first direction.

4. The electronic device according to claim 1, further comprising:
a first optical waveguide element, connected to the waveguide connector and the first photoelectric conversion device; and
a second optical waveguide element, connected to the waveguide connector and the second photoelectric conversion device;
wherein the first optical waveguide element, the waveguide connector, and the second optical waveguide element are configured to form an optical channel for transmitting the optical signal along the first direction.

5. The electronic device according to claim 1, further comprising:
a first optical waveguide element, connected to the waveguide connector and the first photoelectric conversion device; and
a second optical waveguide element, connected to the waveguide connector and the second photoelectric conversion device;
wherein the first optical waveguide element, the waveguide connector and the second optical waveguide element are configured to form a U-shaped optical channel.

6. The electronic device according to claim 5, wherein a part of the first optical waveguide element and the first photoelectric conversion device are located in a same sub-layer of the first circuit layer, and a part of the second optical waveguide element and the second photoelectric conversion device are located in a same sub-layer of the second circuit layer.

7. The electronic device according to claim 5, wherein the first optical waveguide element and the first photoelectric conversion device are located in different sub-layers of the first circuit layer, and the second optical waveguide element and the second photoelectric conversion device are located in different sub-layers of the second circuit layer.

8. The electronic device according to claim 1, wherein a vertical projection of the waveguide connector on the first circuit layer or the second circuit layer overlaps with vertical projections of the first photoelectric conversion device and the second photoelectric conversion device on the first circuit layer or the second circuit layer.

9. The electronic device according to claim 1, wherein a vertical projection of the waveguide connector on the first circuit layer or the second circuit layer does not overlap with vertical projections of the first photoelectric conversion device and the second photoelectric conversion device on the first circuit layer or the second circuit layer.

10. The electronic device according to claim 1, wherein the first circuit block and the first photoelectric conversion device are located in a same sub-layer of the first circuit layer, and the second circuit block and the second photoelectric conversion device are located in a same sub-layer of the second circuit layer.

11. The electronic device according to claim 1, wherein the first circuit block and a part of the first photoelectric conversion device are located in different sub-layers of the first circuit layer, and the second circuit block and a part of the second photoelectric conversion device are located in different sub-layers of the second circuit layer.

12. The electronic device according to claim 1, further comprising:
a photoelectric transport layer, located between the first circuit layer and the second circuit layer, and connected to the first circuit layer and the second circuit layer via a plurality of electrical connectors.

13. The electronic device according to claim 12, wherein a part of the first photoelectric conversion device and a part of the second photoelectric conversion device are disposed in the photoelectric transport layer, and the part of the first photoelectric conversion device is connected to the part of the second photoelectric conversion device via an internal optical waveguide connector.

14. The electronic device according to claim 1, further comprising:
a plurality of waveguide connectors;
a plurality of electrical connectors;
a first photoelectric transport layer, stacked on the first circuit layer, and connected to the first circuit layer via the plurality of electrical connectors;
a waveguide connecting layer, stacked on the first photoelectric transport layer, and connected to the first photoelectric transport layer via the plurality of waveguide connectors; and
a second photoelectric transport layer, stacked on the waveguide connecting layer, connected to the waveguide connecting layer via the plurality of waveguide connectors, and connected to the second circuit layer via the plurality of electrical connectors.

15. The electronic device according to claim 14, wherein a part of the first photoelectric conversion device is disposed in the first photoelectric transport layer, and a part of the second photoelectric conversion device is disposed in the second photoelectric transport layer.
